(19) United States
(12) Patent Application Publication
(10) Pub. No.: US 2023/0267360 A1
(43) Pub. Date: Aug. 24, 2023

(54) ADVANCED QUANTUM PROCESSING SYSTEMS AND METHODS

(71) Applicant: Diraq Pty Ltd, New South Wales (AU)

(72) Inventors: Andrew Steven DZURAK, UNSW Sydney (AU); Wei HUANG, UNSW Sydney (AU); André Luiz SARAIVA DE OLIVEIRA, UNSW Sydney (AU); Jun YONEDA, UNSW Sydney (AU)

(73) Assignee: Diraq Pty Ltd, New South Wales (AU)

(21) Appl. No.: 18/020,510

(22) PCT Filed: Aug. 9, 2021
(86) PCT No.: PCT/AU2021/050869

§ 371 Date: Feb. 9, 2023

(30) Foreign Application Priority Data
Aug. 10, 2020 (AU) 2020902815

(51) Int. Cl. G06N 10/40; G06N 10/70

(52) U.S. Cl. CPC G06N 10/40; G06N 10/70

(57) ABSTRACT

Quantum processing devices and methods for shuttling qubits between a pair of processing elements are disclosed. In particular, a disclosed method for shuttling a qubit from a first processing element to a second processing element in a quantum processing device comprising a plurality of processing elements, includes: applying an optimal bias configuration between the first processing element and the second processing element to shuttle the qubit from the first processing element to the second processing element in a manner that minimizes the time spent by the qubit in one or more state transition points between the first processing element and the second processing element.

### TECHNICAL FIELD

Aspects of the present disclosure are directed an advanced processing apparatus comprising an array of quantum processing elements, and particularly, but not exclusively, to an architecture for performing quantum processing and for transporting quantum information along the array of quantum processing elements.

### BACKGROUND

Developments are ongoing to implement new types of advanced processing apparatus that can implement powerful computations using a different approach than current processors. Such advanced processing apparatus promise computational capacities well beyond current devices. For example, quantum processors are being developed which can perform computations according to the rules of quantum mechanics. Approaches to the realisation of devices for implementing quantum bits (qubits), the basic computational unit of a quantum processor, and quantum architectures, have been explored with different levels of success.

The most promising routes towards large-scale universal quantum computing require quantum error correction, a technique that enables the processing of quantum information using realistic noisy qubits, provided that the noise is below a fault-tolerant threshold.

Some quantum error correction methods, such as ‘surface codes’, allow for error thresholds as high as 1%. Such errors levels can be achieved using a number of qubit platforms. However, to do any meaningful operations with surface codes, a large number of qubits is required and therefore a platform that can be scaled-up to a large number of qubits, such as 10⁸ is required. The requirement for such a large number of qubits creates a challenge in the field of quantum computing, even for the most promising platforms.

In order to manufacture an ‘error-corrected quantum computer’, a scalable architecture is required. Such architectures would ideally incorporate large numbers of qubits, disposed in relatively close proximity to each other, operating in synergy to implement error-corrected quantum computation. In addition, the architectures should be feasible to manufacture.

### SUMMARY

According to a first aspect of the present disclosure, there is provided a method for shuttling a qubit from a first processing element to a second processing element in a quantum processing device, the quantum processing device comprising a plurality of processing elements, the method comprising: applying an optimal bias configuration between the first processing element and the second processing element to shuttle the qubit from the first processing element to the second processing element in a manner that minimizes the time spent by the qubit in one or more state transition points between the first processing element and the second processing element.

The quantum processing device may further include one or more transport elements located between the first processing element and the second processing element and the method may further include applying optimal bias configurations between pairs of the one or more transport elements such that time spent by the qubit in one or more state transition points between the one or more transport elements and/or between processing and transport elements is minimized.

In some embodiments, each of the one or more transport elements has a dwelling bias point at which coherence times of the qubit is highest and shuttling the qubit from the first processing element to the second processing element comprises applying the optimal bias configurations such that the qubit dwells in each of the one or more transport elements at the dwelling bias point.

In some embodiments, the dwelling bias point is obtained by tuning interaction of the qubit spin-orbit and qubit tunnelling effects.

The method may further include determining a cumulative phase rotation introduced in the qubit when the qubit shuttles from the first processing element to the second processing element and correcting the cumulative phase rotation introduced in the qubit once it is shuttled to the second processing element.

In yet other embodiments, the method further includes correcting a phase error or rotation in the qubit by performing dynamical decoupling while the qubit is shuttled to the second processing element and/or once the qubit is shuttled to the second processing element.

In addition, the quantum processing device may also include one or more exchange coupling gates arranged between pairs of processing or transport elements, which are configurable to control the time taken by the qubit to transition from one element to another.

In another aspect of the present disclosure, there is provided a quantum processing apparatus, comprising: a plurality of quantum processing elements configured to operate as qubits; a plurality of quantum processing elements configured to transport quantum information between qubits by shuttling electrons or holes; wherein the quantum processing elements arranged in a predetermined geometry.

Each quantum processing element may be associated with a corresponding electrode; and to shuttle the electrons or holes between a pairs of adjacent processing elements, an optimal bias voltage is applied between the pair of corresponding electrodes to shuttle the qubit between the pair of adjacent processing elements in a manner that minimizes the time spent by the electron or hole in a state transition point between the pair of processing elements.

In some embodiments, one or more exchange coupling gates may be positioned between pairs of quantum processing elements, the one or more exchange coupling gates configured to decrease the potential barrier between the pair of adjacent processing elements when shuttling to minimize the time spent by the electron or hole in a state transition point.

When the qubits are idle (i.e., not being shuttled), the voltage applied to the electrodes of the corresponding processing elements is at a dwelling bias point (typically just below the voltage bias required to transition the qubit from one processing element to another) at which coherence time of the qubit is highest.

Shuttling the qubit between adjacent processing elements comprises applying the optimal bias voltage such that the electron or hole dwells in each of the pair of quantum processing elements at the dwelling bias point.

In some embodiments, the dwelling bias point is obtained by tuning interaction of the qubit spin-orbit and qubit tunnelling effects.

In some embodiments, the quantum processing device may be a silicon based device and in some particular examples, it may be a silicon MOS device. In such systems, the plurality of processing elements are quantum dots with an electron or hole encoding the qubit. Further, the plurality of processing and/or transport elements may form a N X M matrix, where N and M are integer values.

In a third aspect of the present disclosure, there is provided a method for shuttling a qubit from a first processing element to a second processing element in a quantum processing device, the quantum processing device comprising a plurality of processing elements, wherein each of the processing elements has a dwelling bias point at which coherence times of the qubit is highest and shuttling the qubit from the first processing element to the second processing element, and the method comprises applying an optimal bias configuration between the first processing element and the second processing element such that the qubit dwells in each of the one or more transport elements at the dwelling bias point.

In some embodiments, the optimal bias configuration causes the qubit to shuttle between the first processing element and the second processing element in less than 60 nanoseconds.

### BRIEF DESCRIPTION OF DRAWINGS

FIG. 1A is a schematic representation of a large scale quantum computing apparatus.

FIG. 1B is a schematic representation of a top view of a scalable quantum processing device according to some embodiments of the present disclosure.

FIGS. 2A and 2B show schematic views of a pair of quantum dots in accordance with some embodiments of the present disclosure.

FIG. 3 is a flowchart illustrating an example method for calibrating a scalable quantum processing device according to some embodiments of the present disclosure.

FIG. 4 is a stability diagram illustrating a detuning axis according to embodiments of the present disclosure.

FIG. 5 is a chart illustrating qubit frequency as a function of the detuning axis.

FIG. 6 is a chart illustrating coherence times as a function of the detuning axis.

FIG. 7 is flowchart illustrating an example method for performing a 2-qubit operation using qubits located in spaced apart processing elements.

FIG. 8 is a pulse schematic illustrating the ramp rate experiment.

FIG. 9 is a chart illustrating qubit coherence as a function of ramp time.

FIG. 10 is a chart illustrating qubit fidelity as a function of ramp time.

FIG. 11 is a pulse schematic illustrating ESR pulses applied over time and the corresponding state of the detuning axis and the qubit state.

FIG. 12 is a pulse schematic illustrating a spectroscopy experiment according to some embodiments of the present disclosure.

FIG. 13 is a schematic representation of the quantum state tomography experiment.

FIG. 14 is a Bloch sphere representation of reconstructed spin states.

FIG. 15 is a schematic diagram showing a pulse sequence with dynamical decoupling for fidelity characterization.

FIG. 16 is a chart showing echo fringes along with fit results.

FIG. 17 is a chart showing normalized echo amplitudes as a function of number of ramp transfers.

FIG. 18 is a schematic diagram showing a pulse schematic used for measuring ramp time dependence.

FIG. 19 is a chart showing pure transfer error as a function of ramp time.

While the invention is amenable to various modifications and alternative forms, specific embodiments are shown by way of example in the drawings and are described in detail. It should be understood, however, that the drawings and detailed description are not intended to limit the invention to the particular form disclosed. The intention is to cover all modifications, equivalents, and alternatives falling within the spirit and scope of the present invention as defined by the appended claims.

### DETAILED DESCRIPTION

There are a number of engineering challenges associated with scalable quantum computing architectures. One challenge is associated with maintaining coherence of static or idle qubits (i.e., of stored quantum bits of information). Coherence of qubits typically reduces over time due to various factors such as charge and electrical noise.

Another issue with scalable quantum computing architectures is design restrictions associated with nearest-neighbour interactions in quantum information processing codes. Typically, a qubit can interact only with its nearest neighbours. The further apart the qubits, the lower the coupling between them. Because of this, most scalable silicon-based quantum computing architectures require qubits to be densely located (typically less than 50 nanometres from each other). Such closely located qubits often cause other problems. Because each qubit requires control electrodes and charge sense elements (which are also just as densely packed), cross-talk between qubits is often seen. That is, signals provided to control one qubit might inadvertently affect neighbouring qubits.

Yet another issue associated with scalable quantum computing architectures is related to transport of qubits. For quantum processing, there is often a requirement for a qubit to interact with another qubit that is not its nearest neighbour. In such cases, the qubit needs to be transported to a location close to the other qubit (so that they can interact) and then the qubit needs to be transported back to its original location. It is widely understood that such transport or shuttling of qubits over longer distances causes decoherence in the qubit, which is undesirable.

Aspects of the present disclosure attempt to address one or more of these issues. In certain embodiments, the systems and methods described herein extend the coherence of single qubits by storing them in a configuration with minimal influence from charge and electrical noise. To this end, the inventors of the present disclosure have identified optimal bias configurations of processing elements which cause the precession frequency of qubits to become insensitive to small changes in bias voltage and minimize the effect of charge and electrical noise on qubit state decoherence, resulting in higher fidelities. In particular, it is determined that optimal bias configuration for a qubit to dwell in a particular location is adjacent to and just before the bias voltage required to transport the qubit from one location to another. This optimal bias configuration is referred to as “dwell bias point” in this disclosure and the bias voltage at which the qubit shuttles from one location to another is referred to as “transition bias” and “state transition point” in this disclosure.

In yet other aspects of the present disclosure, the methods and systems described herein enable long-range communication between qubits by transporting/shuttling qubits from one location to another with minimal loss of coherence. In particular, inventors of the present disclosure have determined that decoherence during transport/shuttling of a qubit from one location to another can be minimized by ensuring that the time spent by the qubit in the transition bias or state transition point configuration is kept to a minimum. In particular, the inventors have identified that reduced detuning ramp times to transition a qubit from one site to another minimizes decoherence and achieves high-fidelity shuttling of qubits. By ensuring qubits dwell in a site at the dwell bias point and are transitioned from one site to another in short detuning ramp times, aspects of the present disclosure enable qubits to be transported long distances with minimal loss of coherence.

In other aspects of the present disclosure, the described systems and methods aid in relaxing the design restrictions associated with nearest-neighbour interactions in quantum information processing codes and allow qubits to be spaced further apart, but still allowing them to interact with each other. Because qubits can be coherently shuttled from one site to another using the above-mentioned techniques, it is possible to sparsely space processing elements in the scalable quantum processing device with interspersed transport elements. The transport elements can be used to transport qubits from one processing element to another. This sparse spacing of processing elements helps reduce cross-talk in the system while still enabling interactions between the spaced-apart qubits.

It will be appreciated that the dwell bias point and the state transition point may be different for different qubits in the same scalable quantum processing architecture and most likely will be different from the dwell bias points and state transition points of other scalable quantum processing architectures. However, these bias values do not change over time. Accordingly, a scalable quantum processing device can be calibrated sporadically or periodically to determine the dwell bias points and state transition points for each pair of sites in the scalable quantum processing device. These determined points can then be used each time the scalable quantum processing device is required to perform computations.

In addition to the above, inventors of the present disclosure have also determined that phase errors introduced by transporting/shuttling a qubit from one site to another not only remain the same each time the qubit is transported/shuttled from the first site to the second site, but are also correctable.

These and other aspects of the present disclosure will now be described in detail in the following sections.

### Example Scalable Quantum Processing Device

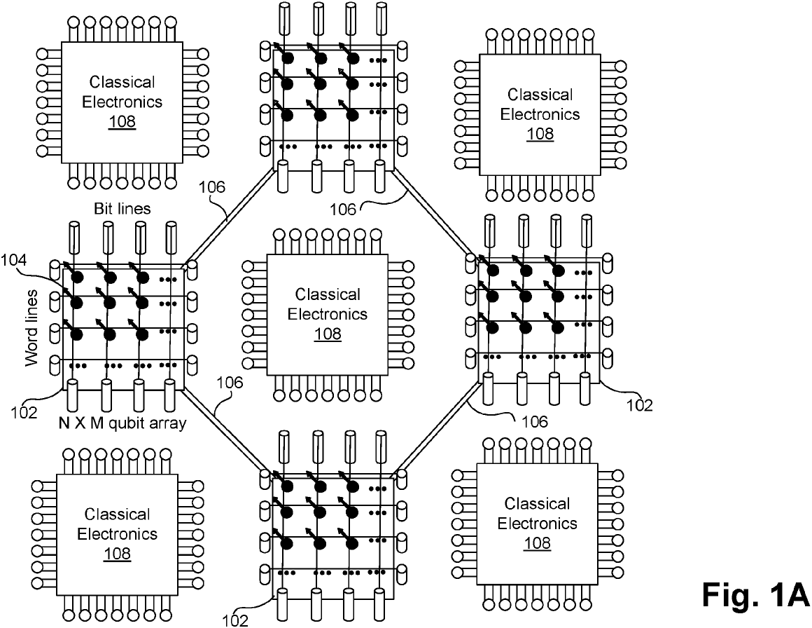

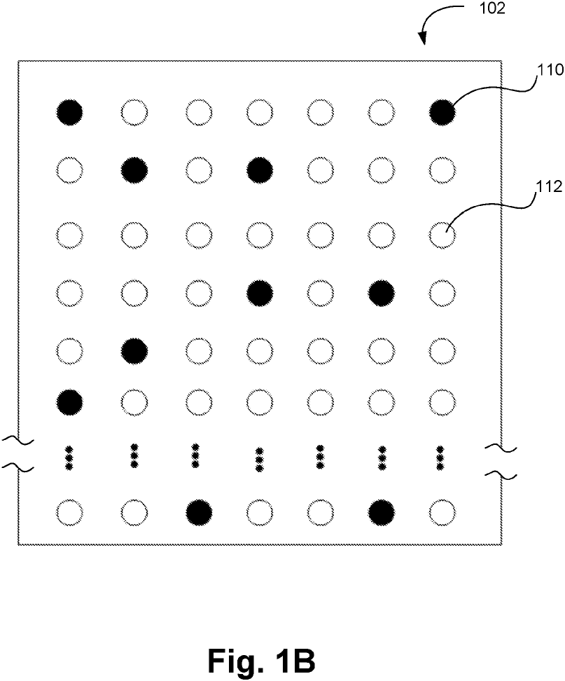

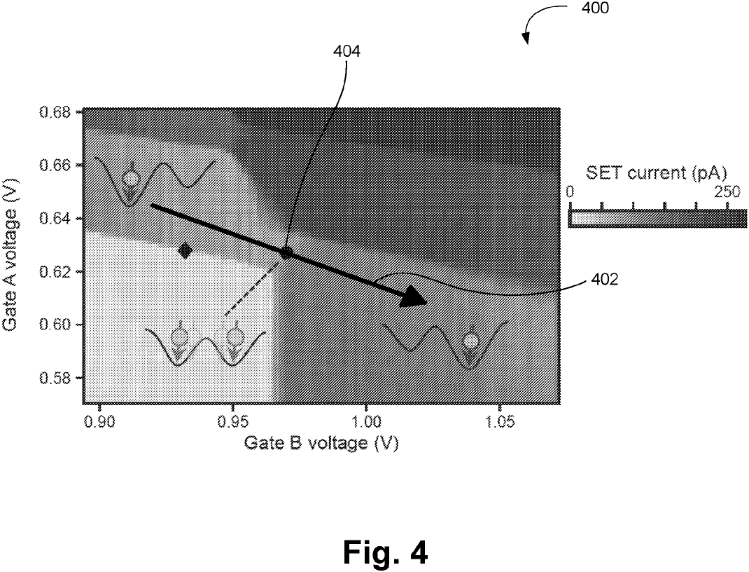

In certain embodiments, aspects of the present disclosure can be implemented in modular quantum processing devices such as those shown in FIG. 1A. In particular, FIG. 1A shows a plurality of qubit arrays or quantum processing modules 102 (each including a plurality of processing elements or qubits 104) that are coupled with each other via long-range qubit couplers 106. Further local electronics 108 intersperse these quantum processing modules 102. In FIG. 1A, the local/classical electronics are placed in the qubit plane. Alternatively, these electronics modules 108 could be located on a separate chip and connected to the qubit modules 102 by flip-chip or other similar technology. The classical electronics may include analog to digital converters, digital to analog converters and as well as vector modulation, such that a minimal number of control lines needs to interface with the outside. An example of such an architecture is described with reference to FIG. 4 in the npi Quantum Information Article, L.M.K. Vandersypen et al, “Interfacing spin qubits in quantum dots and donors-hot, dense, and coherent”, which is incorporated herein by reference.

Further, in some embodiments, the quantum processing device (which may be one of the modules 102 shown in FIG. 1A) in which the presently disclosed methods are performed includes a plurality of processing elements which are interspersed with a plurality of transport elements. The processing elements and transport elements may be arranged in a N X M matrix (where N and M are integer values) in some embodiments.

FIG. 1B illustrates a simplistic top view of such a quantum processing device 102. The processing elements 110 are depicted as solid dots in FIG. 1B and the transport elements 112 are depicted as non-filled dots. The placement of the processing elements 110 and transport elements 112 can be such that the processing elements 110 are located a sufficient distance from each other to prevent crosstalk (which often occurred in previously known architectures where the quantum processing device included processing elements, but no transport elements).

In some embodiments, the processing elements 110 include a silicon/dielectric interface and an electrode arrangement suitable to confine one or more electrons or holes in the silicon, in proximity of the interface, to form one or more quantum dots which are operable as one or more qubits. The transport elements 112 are similarly constructed as quantum dots, with the only difference being that they do not operate as qubits. Instead, qubits dwell in the transport elements 112 by via of tunnelling from an adjacent processing or transport element.

The quantum processing device 102 also includes a plurality of control members (not shown) disposed about the processing elements. The control members include switches which interact with the electrodes to enable quantum operations. A plurality of controls lines are connected to the control members to enable simultaneous operation of a plurality of processing elements.

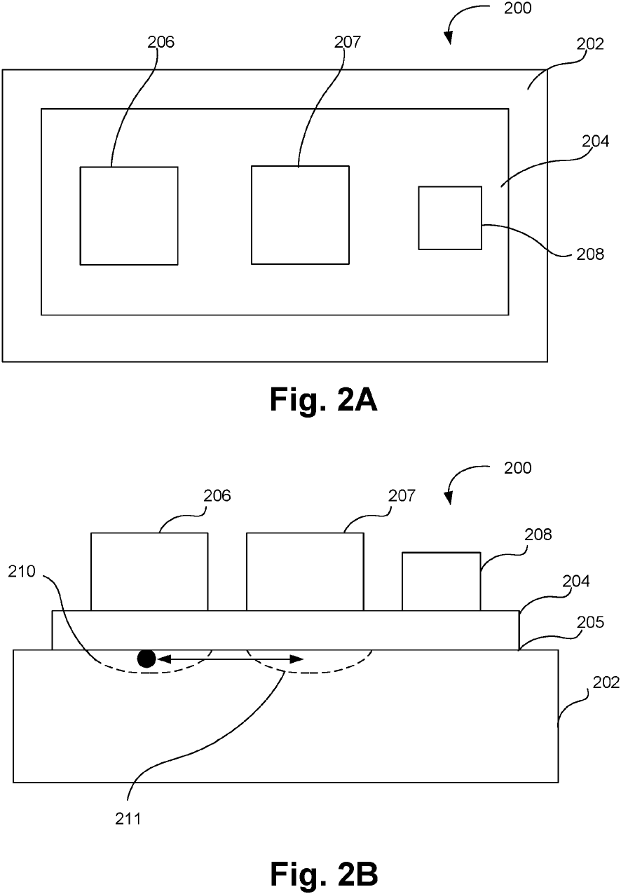

FIG. 2 illustrates a simplified view of a quantum processing device/module 200 (including a processing element 110 and a transport element 112) as shown in FIG. 1B. FIG. 2A is a top view and FIG. 2B is a side cross sectional view. In the embodiment described, the quantum processing device 200 includes a silicon substrate 202 and a dielectric layer 204, which in this example is silicon dioxide. Isotopically enriched silicon ²⁸Si can be used. This may be an epitaxial layer grown on a conventional silicon substrate.

The quantum processing device 200 may include spin qubits – i.e., qubits encoded in the spins of electrons or holes. The implementation of spin qubits in a silicon/silicon dioxide system provides increased spin coherence compared with most compound semiconductors due to the reduced hyperfine coupling of qubits to nuclear spins in the host crystal. Typically, to create the qubits, an electrostatic field is used to confine a small number of electrons in quantum dots.

In order to do this, the quantum processing device 200 includes a first electrode 206 that is operable to form a quantum dot 210 in proximity to the interface 205 between the silicon substrate 202 and the dielectric later 204. FIG. 2B shows area 210 where either electrons or holes may be confined. Sufficiently positive voltages applied to electrode 206 will cause electrons to be confined in the area 210 and be attached to the dielectric layer 204, while sufficiently negative voltages applied to electrode 206 will cause holes to be confined in the area 210 and be adjacent to the dielectric layer 204, respectively.

For example, a single electron can be confined in area 210, thus forming a confined quantum dot. A single qubit can be encoded in the spin of the isolated electron. Alternatively, a qubit can be encoded using the spins of electrons or holes in a single quantum dot. Additional electrode structures can also be employed to aid in confinement of the quantum dot. In an alternative embodiment, a single qubit can be encoded on the spin of one or more electrons or holes of respective one or more quantum dots. Further elements can also be introduced at the interface to promote electron confinement, such as doped regions or dielectric regions. In addition, the overall concentration of electrons at the interface may be modified using an isolated global electrode above or below the interface.

A second electrode 207 associated with a transport element 112 is operable to enable the processing element qubit to be transported to area 211 from area 210 (typically via tunnelling). A difference in potential (or voltage bias) between the first electrode 206 and the second electrode 207 dictates whether the qubit remains in area 210 or moves to area 211. As described previously, the voltage bias required to cause the qubit to shuttle from the processing element 110 to the transport element 112 and vice versa is called the transition bias or “state transition point”. If the potential difference applied between electrodes 206 and 207 is positive and sufficient enough to cause tunnelling of the qubit, the qubit formed under electrode 206 shuttles to the area 211 under electrode 207. Alternatively, if the potential difference applied between electrodes 206 and 207 is negative and sufficient enough to cause tunnelling of the qubit, the qubit under area 211 shuttles back to area 210. The value of the transition bias required to cause the qubit to tunnel from one quantum dot to another depends on the potential barrier between the two quantum dots, the distance between the two quantum dots, etc.

In addition to the processing element 110 and the transport element 112, the quantum processing device 200 may also include a charge sensing element to readout the state of the qubit formed under electrode 206 when it is dwelling under electrode 206, tunnelling to area 211 or dwelling under electrode 207. In the example portion of the quantum processing device shown in FIG. 2, this charge sensing element is depicted as a single electron transistor (SET) 208 adjacent to the processing and transport elements 110 and 112. In other embodiments, different charge sensing elements such as quantum point contact (QPC) sensors, tunnel junction sensors, or gate-based dispersive sensors may be employed on the same plane as the processing and transport elements or in a different plane from the processing and transport elements without departing from the scope of the present disclosure.

In addition, the quantum processing device 200 may also include a control element (not shown) for controlling the spin of the qubits. The control element delivers magnetic microwave signals also known as Electron Spin Resonance signals or ESR signals and RF signals also known as Nuclear Magnetic Resonance signals or NMR signals for controlling the spins of the qubits. In example systems, the control element may be a transmission line, a global control element either as part of the architecture shown in FIGS. 1 and/or 2 or on a different plane or chip from the processing/transport elements.

In some embodiments, the quantum processing device 200 may also include exchange coupling gates (not shown), also referred to as J-gates, between pairs of processing elements, pairs of transport elements, or pairs of processing and transport elements. The exchange coupling gate is typically configured to tune the exchange coupling between two qubit sites and in particular reduce or increase the potential barrier between adjacent qubit sites to decrease or increase the time taken by an electron or hole to transition from one qubit site to the other.

In the scalable quantum computing architecture described herein, a large number of qubit devices configured in accordance with the principles discussed above and illustrated in FIG. 1B and FIG. 2, or configured as modular interconnected structures such as those shown in FIG. 1A operate together to perform error corrected quantum computation.

### Method for Calibrating the Quantum Processing Device

As discussed previously, to enable coherent dwelling and shuttling, systems and methods of the present disclosure calibrate a quantum processing device to identify parameters required for storing and shuttling qubits with minimum coherence loss.

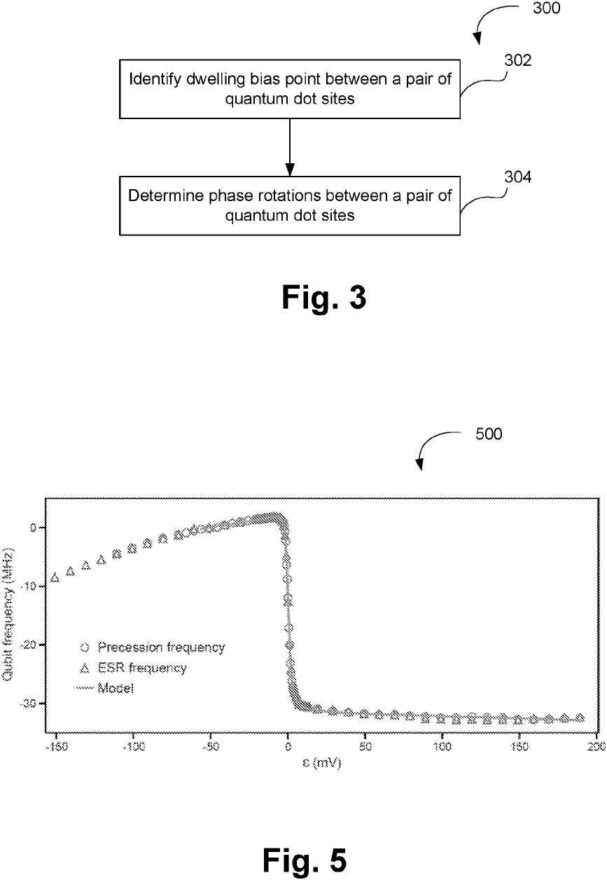

FIG. 3 illustrates an example method 300 for doing so – that is, a method for identifying the parameters for storing and shuttling qubits between two locations with minimum coherence. Method 300 will be described with respect to a pair of quantum dots – e.g., a processing element 110 quantum dot and a transport element 112 quantum dot. However, it will be appreciated that this method can be repeated for all other pairs of nearest neighbour quantum dots in a quantum processing device including between other neighbouring processing elements 110 and transport elements 112, between neighbouring transport elements 112 and between neighbouring processing elements 110.

The method commences at step 302, where a dwelling point between a pair of neighbouring quantum dots is determined – e.g., between quantum dot 210 of processing element 110 and quantum dot 212 of transport element 112. In certain embodiments, this is determined by first determining the transition point between the two quantum dots.

As described previously to transport an electron or hole from one quantum dot to another, e.g., from area 210 to 211, a voltage difference is applied to the two electrodes 206 and 207 such that electrons or holes confined under one electrode move to the area under the other electrode by tunnelling. The areas 210 and 211 will be referred to as quantum dot sites A and B, respectively in this disclosure.

In one example, the difference between the gate voltage of electrode 207 and the inter-dot transition voltage is defined as detuning ε. As the detuning value changes (i.e., as the gate voltage of electrode 207 changes), it changes the energy difference between the spin states localized in individual sites. In another example, detuning axis can be defined as and swept by a combination of gate voltages of electrodes 206 and 207 (and even J gates if they are employed).

FIG. 4 illustrates a stability diagram 400 showing an example of this detuning. The x-axis represents the gate voltage applied at site B and the y-axis represents the gate voltage applied at site A, 207 and 206, respectively. Line 402 defines the detuning axis used for qubit transfer. A charge sensing element (e.g., SET 208) can be used to: a) sense charge at sites A and B, b) to determine whether the qubit is dwelling in site A or site B, c) to determine when the qubit shuttles between the two sites, and d) to determine the transition point. For instance, when a qubit tunnels from site A to site B a blip is noticed in the SET current as site A charge state changes from filled to empty. This blip is interpreted as shuttling of the qubit from site A to site B.

In one example, to determine the transition point, the detuning value ε is increased and the corresponding charge at site A is sensed. The point on the detuning axis where the blip in the sensed charge is observed, is determined to be the transition point. This is defined as ε = 0 and is marked by dot 404 in FIG. 4.

Once the transition point is determined, the dwelling point can be determined. As explained previously, the dwelling point is a point on the detuning axis where there is minimal influence from charge and electrical noise on the qubit. In one embodiment, this dwelling point can be determined based on a determination of the qubit precession frequency and ESR frequency as a function of the detuning axis 402. For example, the detuning axis value can be increased and the qubit frequencies can be detected.

FIG. 5 shows a graph 500 illustrating qubit precession frequency (along the y axis) and ESR frequency as a function of the detuning axis (x-axis). As seen in the graph 500, as the detuning value increases towards ε = 0, i.e., the transition point, the precession frequency and ESR frequency of the qubit steadily increases and then abruptly drops when the detuning axis is at ε = 0 – i.e., when the qubit shuttles to site B. The detuning value at which the sudden change in the precession frequency and ESR frequency is detected is determined to be the transition point. Further, the detuning value at which the qubit frequency becomes insensitive to detuning fluctuations due to charge noise, as a result of competition between Stark shift and tunnelling hybridization, is identified as the dwelling point for that site.

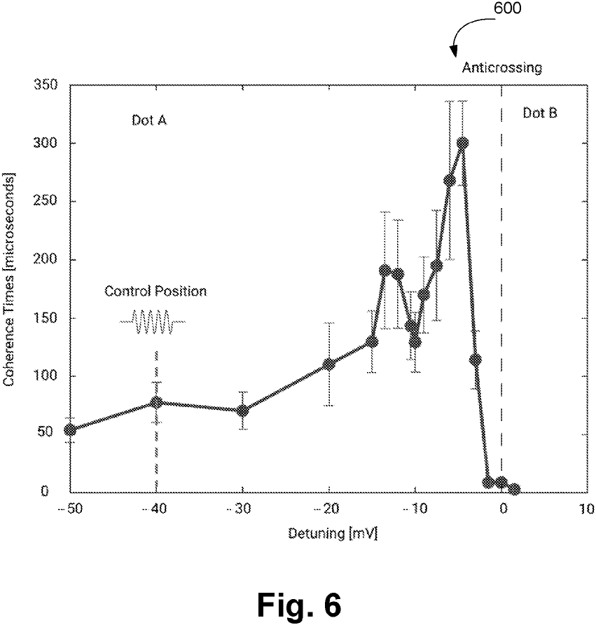

In another example, the dwelling point can be determined by measuring the coherence time for a qubit at different positions along the detuning axis (e.g., using Hahn echo experiment). The point along the detuning axis at which the coherence time of the qubit is the highest is determined to be the dwelling point for that site. FIG. 6 shows a chart 600 illustrating this. As seen from the figure, based on the particular experiment and the particular site, it was determined that the coherence time for the qubit at that site was the highest (approximately 300 microseconds) at a detuning value of approximately -0.5 mV, which is determined to be the dwelling point for that site.

Returning to method 300, once the dwelling point is determined for each of the two sites, a determination is made of the phase rotation that occurs when a qubit shuttles between sites A and B at step 304.

Generally speaking, when a qubit shuttles, the transporting electrons or holes experience electrical and magnetic disturbances, which affect the spin and phase of the electrons/holes causing decoherence in the corresponding qubit.

Further, as the electrons or holes are confined under the dielectric layer 204 and the dielectric layer 204 can have microscopic variations in its structure, a qubit in one quantum dot may behave differently from a qubit in another quantum dot.

Because of these known issues, it was widely believed that transporting a qubit from one quantum dot to another would cause severe spin and phase decoherence in the qubit. Inventors of the present disclosure however have studied the impact of such errors on movement of qubits from one site (e.g., a processing element 110 quantum dot) to another site (e.g., a transport element 112 quantum dot) and have determined that the errors introduced by such movement of qubits (if done quickly and between dwelling points) not only remains the same over time, but are also correctable. In particular, it was determined that a qubit experienced only small polarization errors if transported using the determined dwelling points and using short ramp times, but may in some cases experience phase errors.

In one embodiment, the impact on the qubit (such as rotations, decoherence, depolarization and leakage) caused by shuttling between two sites may be determined using quantum state tomography of a post transfer qubit spin. The impact on the phase of the qubit (such as phase rotations and dephasing) introduced by shuttling between two sites may also be determined by measuring Ramsey fringes for a post-transfer qubit spin. The potentially small influence of the shuttling process may be amplified by repeating the process. In an example, a qubit may be initialized with a particular spin at site A (and preferably at the determined dwelling spot) and then it may be shuttled to site B multiple times and back. Each time the qubit is shuttled to site B and back, its spin phase may be determined by projecting it along multiple axes. In addition, the phase of the qubit spin may also be determined after predetermined dwell times without shuttling the qubit back and forth. Using this, the phase rotations introduced by shuttling the qubit between the pair of sites A and B can be determined.

Once the dwelling point for each site is determined, and the transition point and phase rotations introduced by shuttling the qubit between the two sites are determined, method 300 ends.

Thereafter, when the quantum processing apparatus 100 is utilized for quantum computation and requires a two qubit operation to be performed between qubits located at two spaced apart processing elements, one of the qubits can be shuttled from its original site to the site of the other qubit and then shuttled back once the 2-qubit operation is performed.

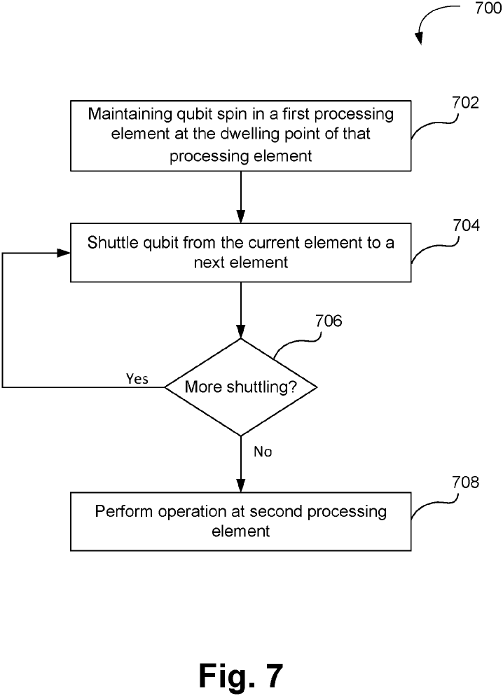

FIG. 7 illustrates an example method 700 for performing a 2-qubit operation using qubits that are located at two processing elements 110 that are spaced apart from each other. In the example method described here, it is assumed that the two processing elements 110 are separated by 5 transport element 112 quantum dots. However, it will be appreciated that this is merely an example and that in implementation, the number of transport elements 112 that a qubit has to shuttle can change.

The method commences at step 702, where the qubit spin is maintained in a first processing element 110 at the dwelling point of that processing element 110. The dwelling point can be computed using method 300.

At step 704, the voltage bias between the first processing element 110 and its neighbouring transport element 112 is ramped to the dwelling point of the neighbouring transport element such that the qubit tunnels from the first processing element 110 to the neighbouring transport element 112. In certain embodiments, the ramp time for doing this is sufficiently small (e.g., approximately 50 ns) to minimize the time spent by the qubit in the state transition point. In other embodiments, the ramp time can be further reduced to a few nanoseconds or possibly to a sub-nanosecond scale to further minimize the time spent by the qubit at the state transition point.

At step 706, a determination is made whether more shuttling is required. For example, because one or more transport elements 112 exist between current transport element 112 and the second processing element 110. If it is determined that more shuttling is required, method step 704 is repeated.

However, each subsequent time step 704 is repeated, the voltage bias between the current transport element 112 and the next transport element 112 is ramped to the dwelling point of the next transport element such that the qubit tunnels from the current transport element to the next transport element.

This process repeats until it is determined at step 706 that no more shuttling is required. Thereafter, the method proceeds to step 708 where the given two-bit operation is performed between the shuttled qubit and the qubit dwelling at the second processing element. In certain embodiments, if any phase rotations occur during the shuttling from the first processing element to the second processing element, the cumulative phase rotation is computed (e.g., based on the known phase rotations for each intermediate shuttle) and the cumulative phase rotation is corrected before the qubit operation is performed.

Once the operation is completed, the shuttling qubit can be shuttled back to the first processing element utilizing a process similar to that described with reference to steps 704 and 706. When the qubit returns to the first processing element, again, the cumulative phase rotation determined during the return shuttling is corrected.

### Experimental Results

Experiments were conducted on a system similar to that shown in FIG. 2.

### Experiment 1: Ramp Rate Dependency

Ramp time is the time taken to detune the bias voltage between sites A and B such that it switches from the dwelling bias point in site A to the dwelling bias point in site B.

Inventors of the present disclosure determined that faster ramp rates showed the highest qubit coherence and qubit fidelity when shuttling between sites A and B.

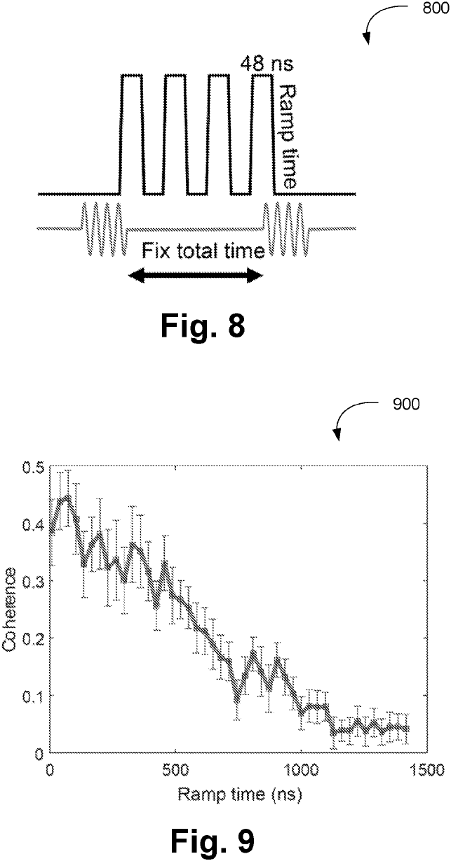

FIG. 8 illustrates a pulse schematic 800 for this experiment. In particular, the qubit superposition state is prepared by applying a half-π ESR pulse on a qubit. This is followed by multiple ramps to shuttle the qubit from site A to site B and a projection ESR pulse.

This was performed a number of times with different ramp times. Coherence and fidelity of the qubit were then measured for the different ramp times. FIG. 9 illustrates a chart 900 showing the measured coherence (y axis) as a function of ramp time (x axis) for a single return trip. As seen in FIG. 9, coherence is negatively correlated with ramp time – i.e., as ramp time increases, the coherence of the qubit decreases.

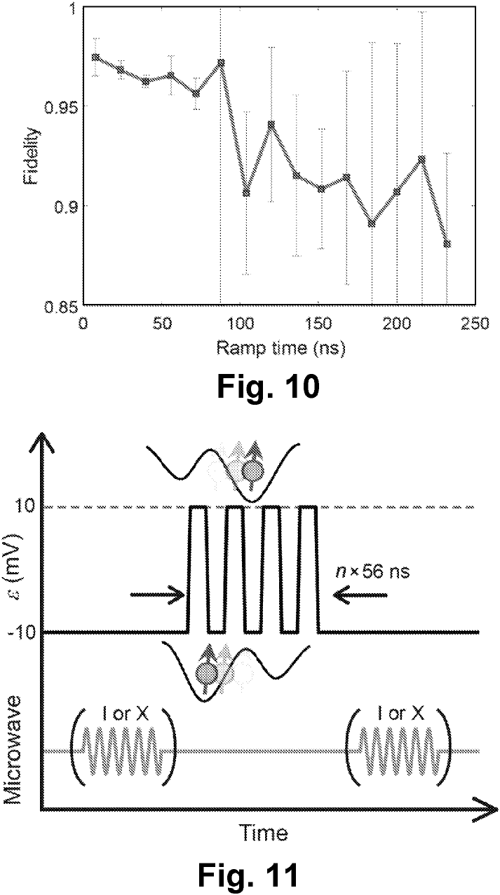

FIG. 10 illustrates a chart 1000 showing qubit fidelity as a function of ramp time. It can be seen from FIG. 10 that the fidelity is highest for shorter ramp times (between approximately 0-80 ns) or faster ramp rates and reduces as the ramp time increases (e.g., above 100 ns in this example.

### Experiment 2: To Confirm Polarization of a Qubit Can Be Transported Between Sites With High Fidelity

In any experiment to confirm whether polarization of a qubit can be transported between sites with high fidelity, the main concern is often that the energy levels of opposite spins in sites A and B would eventually match when the detuning axis value ε becomes equal to the Zeeman splitting, facilitating a spin-flip tunnelling process from site A to B due to the spin-orbit field generated by the electron movement or a small site-difference in spin quantization axes. To avoid the formation of these degeneracy points, the tunnel coupling can be enhanced above the Zeeman energy, e.g., by using J-gates. The other advantage of a large tunnel coupling is that it also suppresses state leakage due to non-adiabatic tunnelling and can make the ramp rate faster.

During the experiment, in order to amplify the polarization error to a measurable level, the spin (initialized in either the down or up state) is repeatedly transferred between the sites. See FIG. 11, which shows a pulse schematic used for the polarization transfer fidelity experiment. 368 ns-long π pulses are turned on (X) and off (I) to prepare both spin-up and spin-down initial states and to measure the probabilities of finding spin-up and spin-down states. The total time in the detuning ramp pulse section increases by 56 ns per detuning ramp from one site to another. The detuning ramps are applied at 56 ns intervals to ensure the spin is transferred to the other site.

In one example, the spin-dependent polarization transfer fidelities, F_pol^{↑} and F_pol^{↓}, are obtained from the probabilities of finding the same (or opposite) spin state as the input state after n consecutive transfer ramps, F_pol^{↑,n} (or 1-F_pol^{↑,n}) and F_pol^{↓,n} (or 1-F_pol^{↓,n}). These probabilities can be modelled as follows treating the transfer-induced spin flip as a memoryless process –

$$\left(\begin{matrix}{F}_{\text{pol}} {}^{↑ , n} & 1 - {F}_{\text{pol}} {}^{↓ , n} \\ 1 - {F}_{\text{pol}} {}^{↑ , n} & {F}_{\text{pol}} {}^{↓ , n}\end{matrix}\right) = {\left(\begin{matrix}{F}_{\text{pol}} {}^{↑} & 1 - {F}_{\text{pol}} {}^{↓} \\ 1 - {F}_{\text{pol}} {}^{↑} & {F}_{\text{pol}} {}^{↓}\end{matrix}\right)}^{n} ,$$

Once values F_pol^{↑} and F_pol^{↓} were computed, it was determined that polarization transfer fidelities for the spin-up and spin-down cases were

$$\left({99.9514}_{- 0.0017}^{+ 0.0008}\right) \%$$

and

$$\left({99.9892}_{- 0.0008}^{+ 0.0008}\right) \% ,$$

respectively. It was determined that the spin polarisation fidelity is high enough to justify neglecting depolarisation effects in following experiments.

### Experiment 3: Determine Whether Qubit Coherence Is Retained After Shuttling

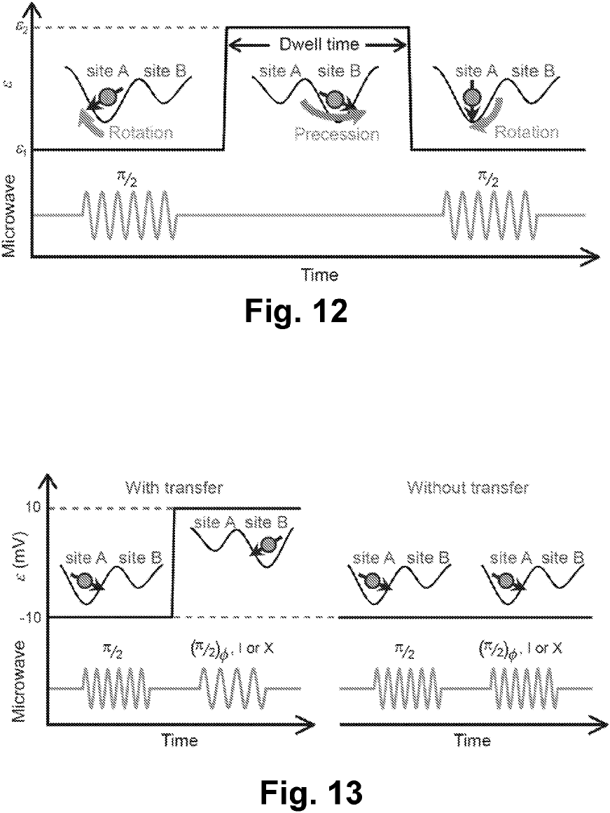

A determination was also made whether qubit coherence is retained after the qubit is moved across sites by employing a Ramsey-type spectroscopy technique. FIG. 12 illustrates a pulse schematic used for the spectroscopy experiment. The spin, prepared in the down state at site A, is first half rotated and then accumulates a phase during the inter-dot detuning pulse for a dwell time t_{dwell}, until a second half-π pulse projects the phase to the polarization (up or down).

In this technique, a qubit spin is initially prepared in an equal superposition of up and down states using a half-π ESR pulse (on resonance with the Larmor frequency at site A). The detuning ε is then plunged on a nanosecond timescale, from ε₁ (in site A) to ε₂ (either site A or B), for a duration of t_{dwell}. The phase acquired during the detour to detuning axis value ε₂ is then projected to spin polarization by a second half-π ESR pulse.

From this experiment, it was determined that the oscillation of the final spin-up probability (pᵤₚ) as a function of time t_{dwell} spent at detuning value ε₂ is visible, irrespective of the dwell time, t_{dwell}, suggesting the whole process is phase coherent. Importantly, the frequency of the qubit starts to rapidly change for ε₂ > 0 and saturates at around 30 MHz (consistent with the qubit resonance frequency difference between sites seen in FIG. 5), indicating that the electron is indeed completely transferred to site B in the saturated region (ε₂ > 5 mV). This leads to the conclusion that spin can be transported into a different site while maintaining phase coherence.

The Ramsey-type spectroscopy technique described above allows accurate measurement of qubit precession frequency as a function of voltage (see FIG. 5) and to establish an understanding of the qubit dispersion in tunnel-coupled quantum dot array.

Since the Ramsey-type spectroscopy measures the energy splitting between instantaneous eigenstates, the contribution from a small spin-flipping tunnelling term can be neglected and a simple four-level model can be used to predict the qubit precession frequency f_{Q} as follows –

$$\begin{matrix}{f}_{\text{Q}} = \frac{{f}_{\text{A}} + {f}_{\text{B}}}{2} + \frac{1}{2} \sqrt{{\left(α ε - \frac{{f}_{\text{A}} - {f}_{\text{B}}}{2}\right)}^{2} + {\left({t}_{\text{c}} - {t}_{\text{s}}\right)}^{2}} - \\ \frac{1}{2} \sqrt{{\left(α ε + \frac{{f}_{\text{A}} - {f}_{\text{B}}}{2}\right)}^{2} + {\left({t}_{\text{c}} + {t}_{\text{s}}\right)}^{2}}\end{matrix}$$

where f_{A(B)} is the bare qubit frequency at site A(B). Here α denotes the leverarm of the gate B voltage change along the ε axis on the energy difference between the localized states, t_{c} the tunnel coupling and tₛ its spin dependence (positive if it is larger for spin-up). f_{A(B)} is further parametrized as f_{A(B)} = f_{Z} + ƞ_{A(B)}ε + (-)Δf_{AB}/2, where f_{Z} is the average of bare qubit frequencies at ε=0, η_{A(B)} accounts for the Stark shift constant and Δf_{AB} gives the qubit frequency difference between sites at ε=0. This explains the qubit frequency f_{Q} measured along the ε axis over 200 mV. This modelling can also be used to determine the origin of detuning axis ε. Using the leverarm extracted from a separate experiment (0.21 eV/V), the best fit is obtained for t_{c} = 104 GHz, tₛ= -3.4 MHz, η_{A(B)} = 39(-7.1) MHz/V and Δf_{AB} = 33.4 MHz. Further, the value of electrode 207 voltage at the interdot transition point is computed in this instance to be 968.85 ± 0.04 mV, which defines experimentally the point where ε = 0. This model also allows precise calculation of the wavefunction hybridization for a given gate voltage condition. It was noticed that the qubit frequency reveals a small spin-dependence in the inter-dot tunnel coupling due to spin-orbit interaction. Furthermore, a dwelling spot (roughly around ε = -7 mV) was discovered where the qubit frequency is first-order insensitive to detuning fluctuations due to charge noise, as a result of competition between the Stark shift and the tunnelling hybridization. It is worth noting that qubit shuttling can be completed within nanoseconds, several orders of magnitude faster than the qubit dephasing time.

### Experiment 4: Influence of Tunnelling to Qubit

A quantum state tomography experiment is performed to determine the influence of tunnelling on a qubit. In particular, quantum state tomography is performed for the spin state with and without a site-to-site transfer.

As schematically shown in FIG. 13, a pre-transfer electron spin state |+y〉 is prepared in site A (ε = -10 mV) by a half-π ESR pulse after initialization to the down state. The spin is then either transferred to site B (ε = +10 mV) or it is left idling in site A by the same amount of time as the transfer would take.

Ten kinds of pre-measurement controls — eight half-p rotations with varying phases (controlled through the microwave phase f), as well as identity (I) and π-rotation (X) operations — are used to effectively change the measurement basis state |ψᵥ〉 of the spin-up readout which follows and to help reduce the measurement bias error.

In addition, the state-preparation and measurement fidelity F_{M,↑(↓)} is obtained by interleaved measurement of the spin-up probabilities with the spin prepared in the down or up state. F_{M,↑(↓)} is measured to be 80.4% (87.9%), allowing for the measurement visibility correction.

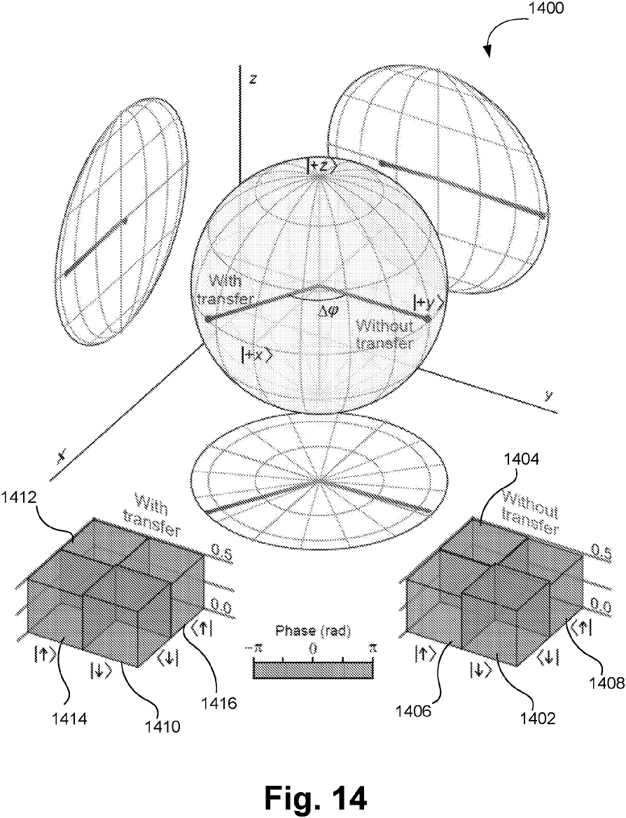

The density matrix of the pre- or post-transfer spin state, ρ, is then reconstructed from the corrected spin-up probabilities, pᵥ, after 4,000 repetitions for each of ten measurement basis states, using maximum likelihood estimation. FIG. 14 shows a Bloch sphere representation 1400 of reconstructed spin states before and after an inter-site transfer process. The projections onto the xy, yz, zx planes are also displayed. The primary net effect of the transfer process is the phase shift Δφ, rooted in the site-dependence of qubit frequency. The insets in FIG. 14 show the amplitude (height) and phase (colour) of the density matrix elements for individual states. For example, without transfer the states 1402 and 1404 have zero phase rotation, whereas the state 1406 has a phase between -π/2 and -π and the state 1408 as a phase between π/2 and π. With transfer, the states 1410, 1412 have zero phase, whereas the state 1414 has a phase between 0 and -π/2 and the state 1416 has a phase between 0 and π/2.

The density matrix of the pre- or post-transfer spin state, ρ is restricted to be non-negative Hermitian and expressed through a complex matrix, L:

$$ρ \left(l\right) = \frac{{L}^{†} L}{\text{tr} \left({L}^{†} L\right)} .$$

L is a 2 × 2 lower triangular matrix whose diagonal elements are real, and has three independent parameters, denoted by ℓ = (ℓ₁, ℓ₂, ℓ₃). To obtain the closest physical ρ, the following cost function, C, is minimized:

$$C \left(l\right) = {\sum }_{v = 1}^{10} \frac{{\left(\left〈{ψ}_{v} \vert ρ \left(l\right) \vert {ψ}_{v}\right〉 - {p}_{v}\right)}^{2}}{2 \left〈{ψ}_{v} \vert ρ \left(l\right) \vert {ψ}_{v}\right〉} .$$

The state fidelity of the resulting ρ is defined by

$${\left(\text{Tr} \left[\sqrt{\sqrt{{ρ}_{\text{ideal}}} ρ \sqrt{{ρ}_{\text{ideal}}}}\right]\right)}^{2} ,$$

where ρ_{ideal} is the density matrix of the closest pure state on the equator of the Bloch sphere 1400. That is, the ideal transfer process is considered as a phase gate which does not alter the spin polarization. We note that this definition of state fidelity implicitly ignores any coherent phase error. To estimate the statistical error, a Monte Carlo simulation is performed to yield a distribution of the estimated state fidelities, from which the one-sigma (68.27%) confidence intervals are calculated around its median value.

This further verifies that the site-to-site qubit transfer can be regarded as a phase rotation gate. Its rotation angle Δφ can be related to the ε-dependent qubit frequency (dominated by the site-dependent Zeeman energy). Comparing the reconstructed spin state after a transfer with the idealised case – i.e., a pure state obtained after applying an ideal phase gate to an exact |+y〉 state – a state fidelity of

$$\left({98.7}_{- 0.8}^{+ 0.6}\right) \%$$

is estimated in the absence of errors in the state preparation and measurement (SPAM). Alternatively, the spin state without a transfer has a fidelity of

$$\left({97.5}_{- 0.8}^{+ 0.5}\right) \%$$

after correcting for SPAM errors. The results indicate that the transfer process is highly coherent and that another quantification method can be used to evaluate the associated errors.

In order to resolve the phase error in a single transport process from SPAM errors, a sequence is employed where the transport ramp pulses are repeated many times between state preparation and measurement. The remaining spin coherence can be evaluated using the Ramsey-interference technique. This protocol amplifies phase errors, leading to a decay of the phase oscillation amplitude with the number of transfer cycles, n. If the error probability of consecutive transfers is uncorrelated, the amplitude decay will be exponential.

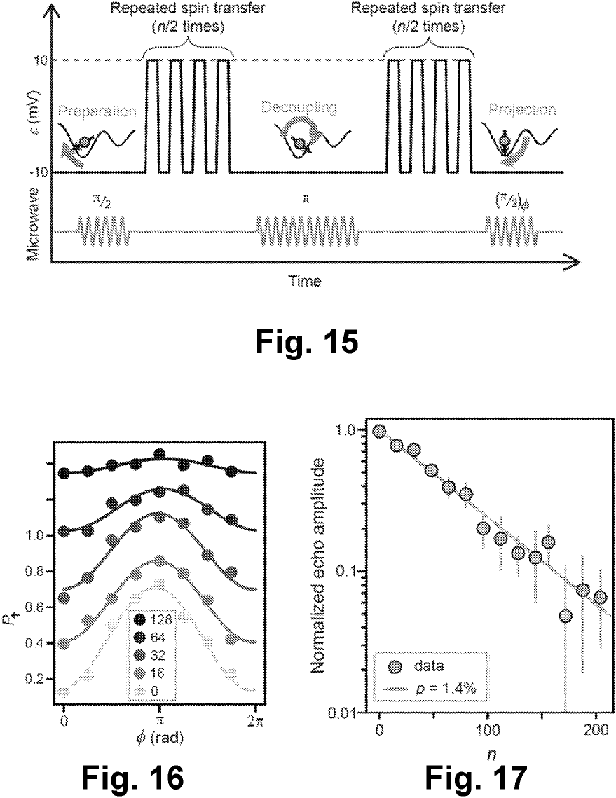

Further, to improve the transfer fidelity, as well as investigate the noise spectrum, a dynamical decoupling step is introduced in the ramp sequence. The protocol shown in FIG. 15 is adopted, where a decoupling π pulse is applied between two identical series of transfer ramps. The echo fringes (see FIG. 16) are measured by sweeping the angle ϕ of the projection axis, revealing that the fringe phase does not change with the transfer cycles, as expected. The amplitude decay of the echo fringes as a function of n ramp transfers (see FIG. 17) yields a phase error per transfer of

$$\left({1.50}_{- 0.13}^{+ 0.14}\right) \% .$$

This means that the dominant part of phase error induced in the transfer process cannot be refocused.

This inefficiency of the dynamical decoupling pulse suggests that the underlying error mechanism is not dominated by either the slow spontaneous flips of the residual ²⁹Si nuclear spins or conventional charge noise with a 1/f-type spectrum (e.g., fluctuation in quantum-dot levels).

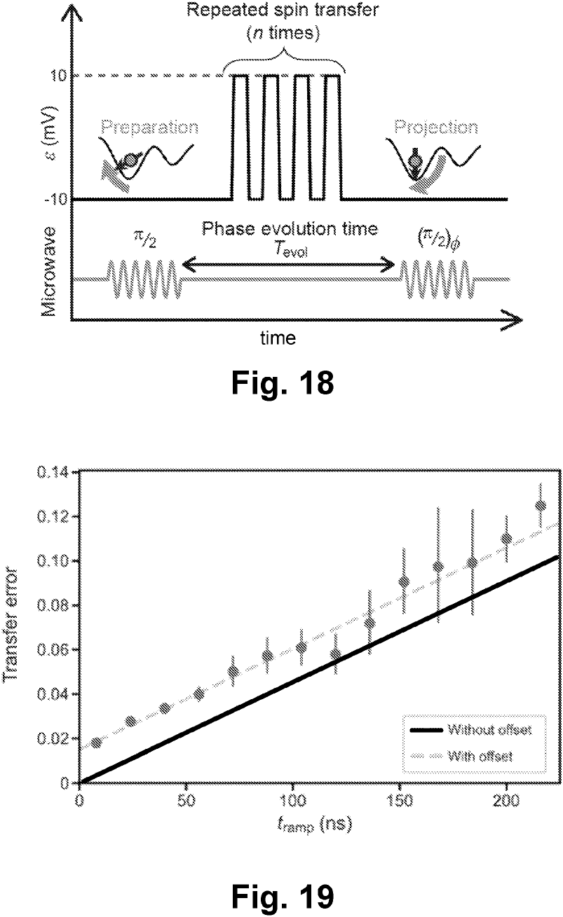

Further still, experiments were conducted by varying the ramp rate as shown in FIG. 18. In particular, the ramp time was varied, while the dwelling time in a particular qubit site was fixed. Studying the influence of the detuning ramp rate using this technique, verified that a slower ramp rate degrades the transfer fidelity (see FIG. 19). This rules out any diabaticity effects – the detuning ramp speed adopted is already adiabatic with relation to the tunnelling energy gap and the valley splitting. A theoretical framework based on diabaticity effects caused by the 1/f detuning noise correctly captures the qualitative ramp time dependence – the slower the ramps, the more time is spent at the unfavourable inter-dot transition region, leading to noise-induced excitations. The experimental data is best described by accounting for an overall shift of the infidelity by approximately 1.5%, independently of the ramp rate. This could indicate the presence of some source of error per transfer that is not caused by the time spent at the inter-dot transition region.

The observed amount of coherence loss of ~2% per transfer corresponds to a spin transfer across ~50 sites before the phase coherence decays to 1/e, or a distance ~2 mm (assuming a 40 nm site spacing). If only the spin polarisation is needed (e.g. for qubit readout), the electron can be transported over 2500 sites or ~100 mm before the polarization decays to 1/e for the spin-up case. While this accuracy in the spin transfer contends that coherent coupling between remote spins is achievable, a fault-tolerant quantum computing architecture relying on qubit movement will require a device setup tailored to enhance the transfer fidelity. From the experiments above, the following desirable features can be identified: the ability to electrostatically control the inter-dot tunnelling rate to guarantee an adiabatic passage; a reduction in the difference of Larmor frequencies in neighbouring sites, achievable by controlling the spin-orbit coupling or operating at lower magnetic fields, and improvements in the fabrication process leading to less charge noise.

It will be appreciated that although the systems and methods described above illustrate silicon metal-oxide semiconductor (MOS) quantum dots, the presently disclosed systems and methods can be applied in silicon-germanium systems as well.

Further, the architectures illustrated in FIGS. 1 and 2 are merely examples of suitable scalable quantum computing architectures in which aspects of the present invention can be implemented. It will be appreciated that the disclosed embodiments can be implemented in any other suitable architectures.

The term “comprising” (and its grammatical variations) as used herein are used in the inclusive sense of “having” or “including” and not in the sense of “consisting only of”.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method for shuttling a qubit from a first processing element to a second processing element in a quantum processing device, the quantum processing device comprising a plurality of processing elements, the method comprising:
applying an optimal bias configuration between the first processing element and the second processing element to shuttle the qubit from the first processing element to the second processing element in a manner that minimizes the time spent by the qubit in one or more state transition points between the first processing element and the second processing element.

2. The method of claim 1, wherein the quantum processing device further includes one or more transport elements located between the first processing element and the second processing element and the method further comprises applying optimal bias configurations between pairs of the one or more transport elements such that time spent by the qubit in one or more state transition points between the one or more transport elements and/or between processing and transport elements is minimized.

3. The method of claim 2, wherein each of the one or more transport elements have a dwelling bias point at which coherence times of the qubit is highest and shuttling the qubit from the first processing element to the second processing element comprises applying the optimal bias configurations such that the qubit dwells in each of the one or more transport elements at the dwelling bias point.

4. The method of any of the preceding claims, further comprising:
determining a cumulative phase rotation introduced in the qubit when the qubit shuttles from the first processing element to the second processing element; and
correcting the cumulative phase rotation introduced in the qubit once it is shuttled to the second processing element.

5. The method of claim 3, wherein the dwelling bias point is obtained by tuning interaction of the qubit spin-orbit and qubit tunneling effects.

6. The method of any of the preceding claims where the quantum processing device is a silicon based system.

7. The method of claim 6, wherein the quantum processing device is a silicon MOS system.

8. The method of claim 7, wherein the plurality of processing elements are quantum dots with an electron or hole encoding the qubit.

9. The method of any of the preceding claims, further comprising correcting a phase error or rotation in the qubit by performing dynamical decoupling while the qubit is shuttled to the second processing element and/or once the qubit is shuttled to the second processing element.

10. The method of any of the preceding claims, wherein the plurality of processing elements form a N X M matrix, where N and M are integer values.

11. The method of any of the preceding claims, wherein the quantum processing device further comprising one or more exchange coupling gates arranged between pairs of processing or transport elements, the exchange coupling gate configurable to control the time taken by the qubit to transition from one element to another.

12. A quantum processing device, comprising:
a plurality of quantum processing elements configured to operate as qubits;
a plurality of quantum processing elements configured to transport quantum information between qubits by shuttling electrons or holes;
the quantum processing elements arranged in a predetermined geometry.

13. The quantum processing device of claim 12, wherein:
each quantum processing element is associated with a corresponding electrode; and
wherein to shuttle the electrons or holes between a pair of adjacent processing elements, an optimal bias voltage is applied between the pair of corresponding electrodes to shuttle the qubit between the pair of adjacent processing elements in a manner that minimizes the time spent by the electron or hole in a state transition point between the pair of processing elements.

14. The quantum processing device of claim 12 further comprising:
one or more exchange coupling gates between pairs of quantum processing elements, the one or more exchange coupling gates configured to decrease the potential barrier between the pair of adjacent processing elements when shuttling to minimize the time spent by the electron or hole in a state transition point.

15. The quantum processing device of any one of claims 12-14, wherein when a qubit is in an idle state, a voltage applied to the corresponding processing element maintains the qubit at a dwelling bias point at which coherence time of the qubit is highest.

16. The quantum processing device of claim 15, wherein shuttling the qubit between adjacent processing elements comprises applying the optimal bias voltage such that the electron or hole dwells in each of the pair of quantum processing elements at the dwelling bias point.

17. The quantum processing device of claim 15 or 16, wherein the dwelling bias point is obtained by tuning interaction of the qubit spin-orbit and qubit tunneling effects.

18. The quantum processing device of any one of claims 12-17 wherein the quantum processing device is a silicon based system.

19. The quantum processing device of claim 18, wherein the quantum processing device is a silicon MOS system.

20. The quantum processing device of claim 19, wherein the plurality of qubits are quantum dots.

21. The quantum processing device of any one of claims 12-20 wherein the plurality of processing elements form a N X M matrix, where N and M are integer values.

22. A method for shuttling a qubit from a first processing element to a second processing element in a quantum processing device, the quantum processing device comprising a plurality of processing elements, wherein each of the processing elements has a dwelling bias point at which coherence times of the qubit is highest and shuttling the qubit from the first processing element to the second processing element comprises applying an optimal bias configuration between the first processing element and the second processing element such that the qubit dwells in each of the one or more transport elements at the dwelling bias point.

23. The method of claim 22 wherein the optimal bias configuration causes the qubit to shuttle between the first processing element and the second processing element in less than 60 nanoseconds.
